(19) United States
(12) Patent Application Publication
(10) Pub. No.: US 2023/0213555 A1
(43) Pub. Date: Jul. 6, 2023

(54) TESTING SUBSTRATE AND MANUFACTURING METHOD THEREOF AND PROBE CARD

(71) Applicant: HERMES TESTING SOLUTIONS INC., Hsinchu City (TW)

(72) Inventors: Wen-Yuan Hsu, Hsinchu City (TW); Chun-Hsiung Chou, Hsinchu City (TW)

(73) Assignee: HERMES TESTING SOLUTIONS INC., Hsinchu City (TW)

(21) Appl. No.: 17/687,671

(22) Filed: Mar. 6, 2022

(30) Foreign Application Priority Data
Dec. 30, 2021 (TW) 110149526

(51) Int. Cl. G01R 1/073

(52) U.S. Cl. CPC G01R 1/07342

(57) ABSTRACT

A testing substrate includes a substrate and a first build-up structure. The substrate has a first surface and a second surface opposite to each other. The substrate includes a first conductive pattern. The first conductive pattern includes a plurality of conductive connectors, and each conductive connector penetrates the substrate from the first surface to the second surface of the substrate. The first build-up structure is arranged on the first surface. The first build-up structure has a second conductive pattern. The first conductive pattern is electrically connected to the second conductive pattern, and the size of the first conductive pattern is larger than or equal to the size of the second conductive pattern. A manufacturing method of the testing substrate and a probe card are also provided.

### CROSS-REFERENCE TO RELATED APPLICATION

This application claims the priority benefit of Taiwan application serial no. 110149526, filed on December 30, 2021. The entirety of the above-mentioned patent application is hereby incorporated by reference herein and made a part of this specification.

### BACKGROUND

### Technical Field

The disclosure relates to a substrate, a manufacturing method thereof, and a testing device, and more particularly relates to a testing substrate, a manufacturing method thereof, and a probe card.

### Description of Related Art

Generally speaking, the testing substrate of a probe card has a probe end and a printed circuit board end that are opposite to each other, and the probe end is used to connect to a wafer. As the semiconductor manufacturing processes continue to shrink, the density of metal pads on the wafer increases and the spacing decreases, and correspondingly the probe needs to have the spacing decreased. For this reason, the design of the corresponding testing substrate and probe card becomes very important. Therefore, how to reduce the manufacturing cost of the probe card and improve the yield and reliability is a challenge.

### SUMMARY

The disclosure provides a testing substrate, a manufacturing method thereof, and a probe card, which reduce the manufacturing cost of the probe card and improve the yield.

A testing substrate according to an embodiment of the disclosure includes a substrate and a first build-up structure. The substrate has a first surface and a second surface opposite to each other. The substrate includes a first conductive pattern. The first conductive pattern includes a plurality of conductive connectors, and each of the conductive connectors penetrates the substrate from the first surface to the second surface of the substrate. The first build-up structure is arranged on the first surface. The first build-up structure includes a second conductive pattern. The first conductive pattern is electrically connected to the second conductive pattern, and a size of the first conductive pattern is larger than or equal to a size of the second conductive pattern.

In an embodiment of the disclosure, the first build-up structure includes a plurality of first patterned conductive layers and a plurality of first dielectric layers that are stacked alternately.

In an embodiment of the disclosure, the testing substrate further includes a second build-up structure arranged on a surface of the first build-up structure opposite to the substrate. A first bonding interface of a dielectric-to-dielectric bonding interface and a metal-to-metal bonding interface is formed between the first build-up structure and the second build-up structure.

In an embodiment of the disclosure, the second build-up structure includes a plurality of second patterned conductive layers and a plurality of second dielectric layers that are stacked alternately.

In an embodiment of the disclosure, the testing substrate further includes a circuit carrier arranged on the second surface. The circuit carrier includes a multi-layer ceramic carrier or a multi-layer organic carrier.

In an embodiment of the disclosure, a second bonding interface of a dielectric-to-dielectric bonding interface and a metal-to-metal bonding interface is formed between the substrate and the circuit carrier; or a plurality of conductive terminals are provided between the substrate and the circuit carrier.

A manufacturing method of a testing substrate according to an embodiment of the disclosure at least includes the following. A substrate having a first surface and a second surface opposite to each other is provided. A first conductive pattern is formed in the substrate.

The first conductive pattern includes a plurality of conductive connectors, and each of the conductive connectors penetrates the substrate from the first surface to the second surface of the substrate. A first build-up structure is formed on the first surface by performing a build-up process. The first build-up structure includes a second conductive pattern. The first conductive pattern is electrically connected to the second conductive pattern. A size of the first conductive pattern is larger than or equal to a size of the second conductive pattern.

In an embodiment of the disclosure, the manufacturing method further includes the following. A second build-up structure is bonded to the first build-up structure by a hybrid bonding process.

In an embodiment of the disclosure, the manufacturing method further includes the following. A circuit carrier is bonded to the second surface by a hybrid bonding process. The circuit carrier is bonded to the second surface by a plurality of conductive terminals.

A probe card according to an embodiment of the disclosure includes a testing substrate, a plurality of probes, and a printed circuit board. The testing substrate includes a substrate and a first build-up structure. The substrate has a first surface and a second surface opposite to each other. The substrate includes a first conductive pattern. The first conductive pattern includes a plurality of conductive connectors, and each of the conductive connectors penetrates the substrate from the first surface to the second surface of the substrate. The first build-up structure is arranged on the first surface. The first build-up structure includes a second conductive pattern. The first conductive pattern is electrically connected to the second conductive pattern, and a size of the first conductive pattern is larger than or equal to a size of the second conductive pattern. The testing substrate is located between the printed circuit board and the plurality of probes.

Based on the above, the testing substrate of the disclosure has a design that combines a plurality of conductive connectors penetrating two surfaces of the substrate and the build-up structure, and during the manufacturing processes, electrical tests can be performed simultaneously on the two surfaces to accurately monitor the production yield. Finally, after the fabrication of the testing substrate is completed, the good products can be taken out simply by cutting the testing substrate, and then the subsequent processes can be performed to complete the probe card required. Accordingly, the manufacturing cost is reduced and the yield and reliability are improved.

In order to make the above-mentioned features and advantages of the disclosure easier to understand, the following embodiments are described in detail with reference to the accompanying drawings as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A to FIG. 1C are schematic partial cross-sectional views of some steps of a manufacturing method of a testing substrate according to some embodiments of the disclosure.

FIG. 1D is a schematic cross-sectional view of performing an electrical test on a testing substrate according to some embodiments of the disclosure.

FIG. 1E is a schematic top view of a testing substrate according to some embodiments of the disclosure.

FIG. 2A to FIG. 2C are schematic partial cross-sectional views of some steps of a manufacturing method of a testing substrate according to some embodiments of the disclosure.

FIG. 3 is a schematic partial cross-sectional view of a testing substrate according to some embodiments of the disclosure.

FIG. 4 is a schematic partial cross-sectional view of a testing substrate according to some embodiments of the disclosure.

FIG. 5 is a schematic partial cross-sectional view of a probe card according to some embodiments of the disclosure.

FIG. 6 is a schematic partial cross-sectional view of a probe card according to some embodiments of the disclosure.

### DETAILED DESCRIPTION OF DISCLOSED EMBODIMENTS

Directional terms (such as up, down, right, left, front, back, top, and bottom) as used herein serve as reference only to the drawings and are not intended to imply absolute orientation.

Unless explicitly stated otherwise, any method described herein should not be construed as requiring to perform the steps in a particular order.

The disclosure is more fully described with reference to the drawings of the embodiments. However, the disclosure may be embodied in various forms and should not be construed as being limited to the embodiments described herein. The thickness, dimensions or size of any layer or region in the drawings may be exaggerated for clarity. The same or similar reference numerals are used to denote the same or similar elements, and will not be repeatly described in the following paragraphs.

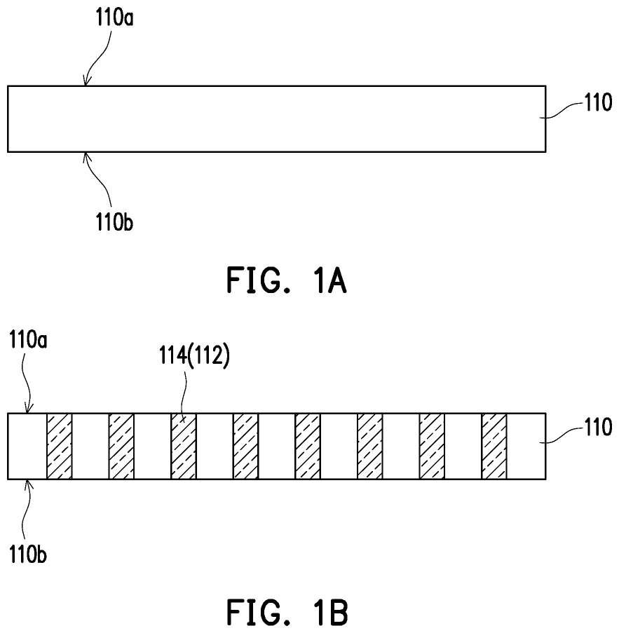

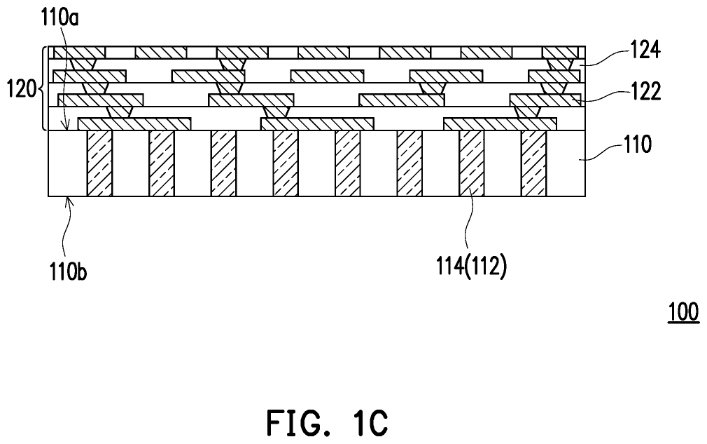

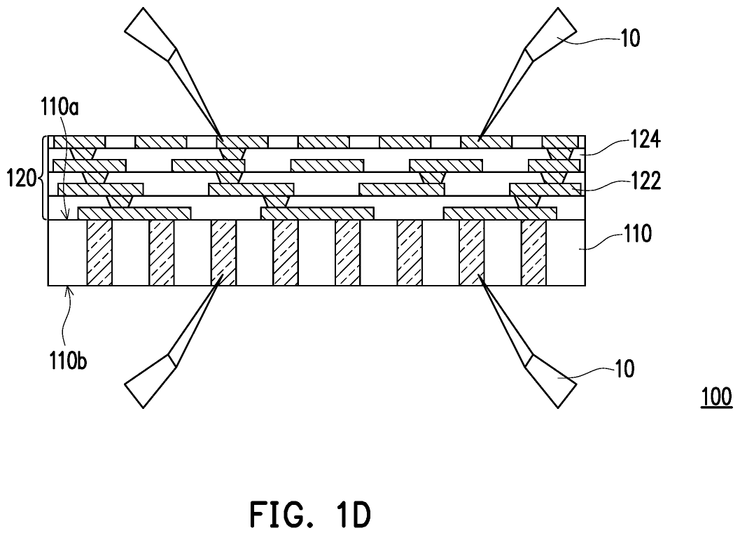

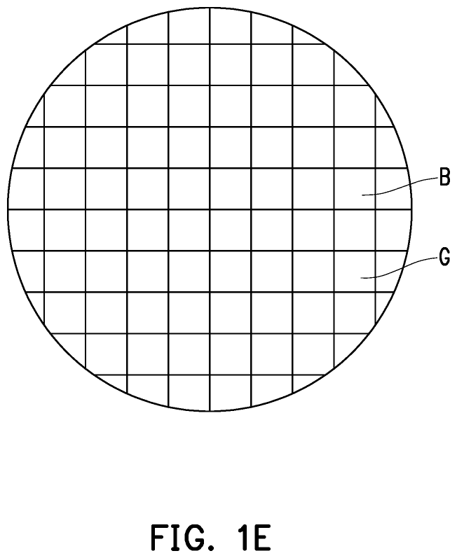

FIG. 1A to FIG. 1C are schematic partial cross-sectional views of some steps of a manufacturing method of a testing substrate according to some embodiments of the disclosure.

FIG. 1D is a schematic cross-sectional view of performing an electrical test on the testing substrate according to some embodiments of the disclosure. FIG. 1E is a schematic top view of the testing substrate according to some embodiments of the disclosure.

Referring to FIG. 1A, in the present embodiment, the manufacturing processes of the testing substrate may include the following steps. First, a substrate 110 having a first surface 110a and a second surface 110b opposite to each other is provided. In some embodiments, the material of the substrate 110 may be glass, a silicon wafer or other suitable materials that can withstand the subsequent processes and can be used to form subsequent conductive patterns.

Referring to FIG. 1B, a first conductive pattern 112 is formed in the substrate 110. The first conductive pattern 112 includes a plurality of conductive connectors 114, and each conductive connector 114 penetrates the substrate 110 from the first surface 110a to the second surface 110b of the substrate 110. Here, the first conductive pattern 112 is formed by first forming a required hole through a suitable drilling process, and then forming a conductive material in the hole through a process of filling, screen printing, electroless plating, electroplating or a combination of the foregoing. The conductive material may be composed of metal (such as copper, aluminum, nickel, gold, silver, tin, platinum, and palladium), graphite or other suitable conductive materials, but the disclosure is not limited thereto.

Referring to FIG. 1C to FIG. 1E, a build-up process is performed to form a first build-up structure 120 on the first surface 110a. The first build-up structure 120 has a second conductive pattern 122, and the first conductive pattern 112 is electrically connected to the second conductive pattern 122. In addition, the size of the first conductive pattern 112 may be larger than or equal to the size of the second conductive pattern 122. After the aforementioned processes are performed, the fabrication of the testing substrate 100 of the present embodiment is substantially completed. Accordingly, the testing substrate 100 of the present embodiment has a design that combines a plurality of conductive connectors 114 penetrating two surfaces (the first surface 110a and the second surface 110b) of the substrate and the build-up structure (the first build-up structure 120), and during the manufacturing processes, electrical tests can be performed simultaneously on the two surfaces (the first surface 110a and the second surface 110b) to accurately monitor the production yield (for example, electrical tests are performed on the first surface 110a and the second surface 110b with flying probes 10, as shown in FIG. 1D).

Finally, after the fabrication of the testing substrate 100 is completed, the good products can be taken out simply by cutting the testing substrate 100 (for example, some rectangular blocks in FIG. 1E may be good products G, and some rectangular blocks may be bad products B), and then the subsequent processes can be performed to complete a probe card required. Accordingly, the manufacturing cost is reduced and the yield and reliability are improved.

In some embodiments, when the size of the conductive pattern (the first conductive pattern 112) of the substrate 110 is larger than the size of the conductive pattern (the second conductive pattern 122) of the build-up structure (the first build-up structure 120), the spacing between two ends of the testing substrate 100 can be satisfied. Therefore, it is possible to further reduce the manufacturing cost and improve the yield and reliability while satisfying the spacing between two ends of the testing substrate 100. Nevertheless, the disclosure is not limited thereto, and the size of the first conductive pattern 112 may also be equal to the size of the second conductive pattern 122. Here, the size of the first conductive pattern 112 and the size of the second conductive pattern 122 may be the spacing between the first conductive patterns 112 and the spacing between the second conductive patterns 122. The spacing may be defined as a distance between the center points of two adjacent metal pads of the first conductive pattern 112 and the second conductive pattern 122, but the disclosure is not limited thereto, and the spacing can be defined in other ways as appropriate. In addition, the schematic cross-sectional view of FIG. 1C may correspond to any rectangular block in FIG. 1E.

In some embodiments, the bonding spacing between two ends of the testing substrate is, for example, 500 μm to 1000 μm at the printed circuit board end, and at least smaller than 40 μm at the probe end. In addition, the bonding spacing between the substrate 110 and the first build-up structure 120 is between the bonding spacings at two ends of the testing substrate. For example, the bonding spacing between the substrate 110 and the first build-up structure 120 is, for example, 200 μm, but the disclosure is not limited thereto. The aforementioned bonding spacing may be adjusted according to actual design requirements.

In some embodiments, since the first build-up structure 120 is formed on the substrate 110 by the build-up process, the substrate 110 and the first build-up structure 120 may be bonded without solder balls/solder paste, which can prevent failure in bridging and bonding the thin film and the substrate after reflow, but the disclosure is not limited thereto.

In some embodiments, the first build-up structure 120 is formed by alternately stacking a plurality of first patterned conductive layers (for example, the second conductive patterns 122) and a plurality of first dielectric layers 124 (thin films). The material of the plurality of first patterned conductive layers (for example, the second conductive patterns 122) may include copper, gold, nickel, aluminum, platinum, tin, a combination of the foregoing, an alloy of the foregoing, or other suitable conductive materials. The material of the first dielectric layer 124 may include a fluorine film (Polyfluoroalkoxy, PFA), a liquid insulating material, a dry film or other suitable electrical insulating materials.

In some embodiments, the first build-up structure 120 is directly built on the substrate 110. In other words, the first build-up structure 120 directly contacts the substrate 110. Furthermore, compared with the structure of a through ceramic via (TCV) which has unstable material properties, a limited size, and high cost (at least 10 times higher than the cost of a through glass via), according to actual design requirements, when the material of the substrate 110 of the present embodiment is glass, the conductive connector 114 can be regarded as a through glass via (TGV); and when the material of the substrate 110 of the present embodiment is a silicon wafer, the conductive connector 114 can be regarded as a through silicon via (TSV). The aforementioned substrates 110 all allow a thin film structure (the first build-up structure 120) to be built directly thereon, and therefore, can overcome the problem caused by the through ceramic via. Nevertheless, the disclosure is not limited thereto.

It is noted here that the following embodiments continue to use the reference numerals and some of the contents of the aforementioned embodiment. The same or similar reference numerals are used to denote the same or similar elements, and repeated description will be omitted. Please refer to the foregoing embodiment for the omitted description, which will not be repeated hereinafter.

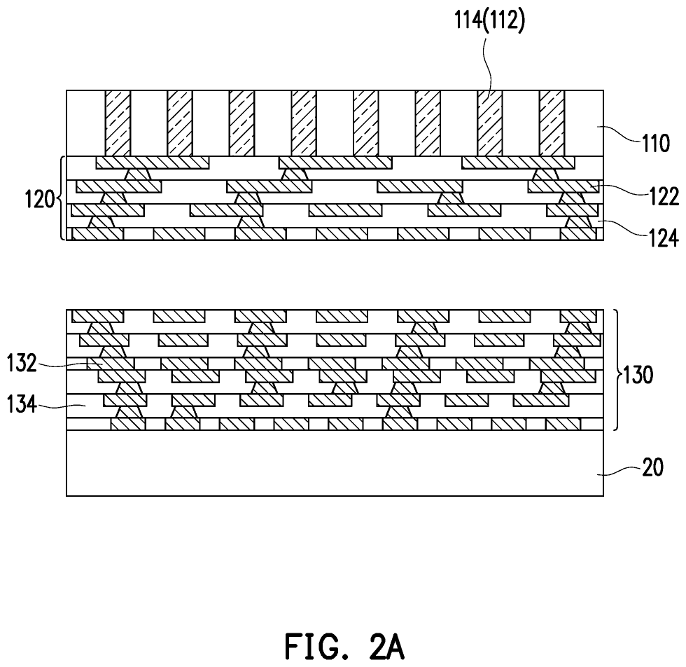

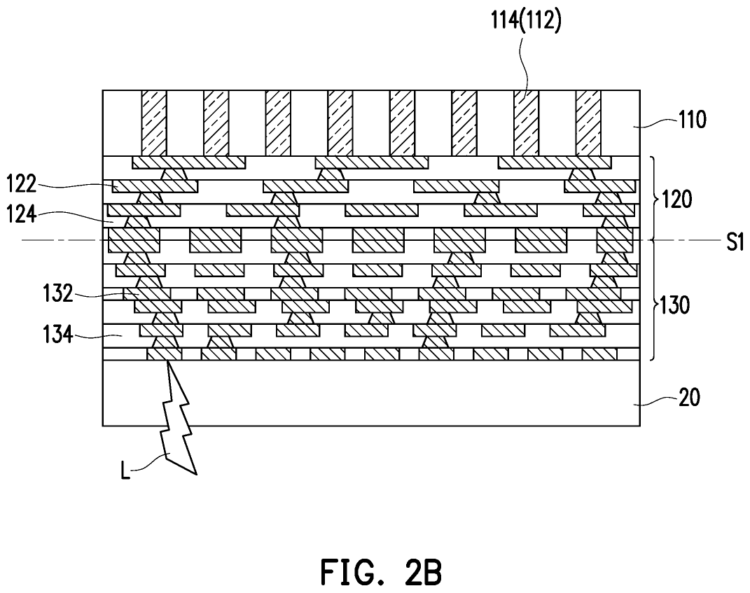

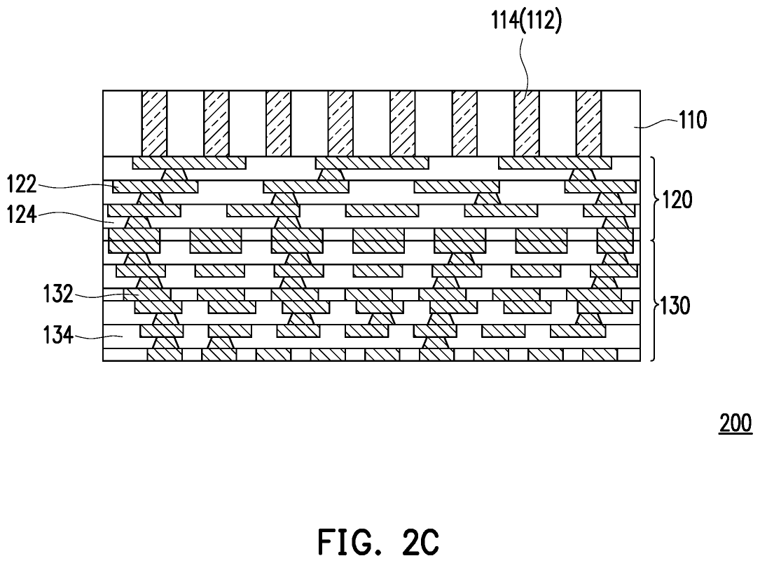

FIG. 2A to FIG. 2C are schematic partial cross-sectional views of some steps of a manufacturing method of a testing substrate according to some embodiments of the disclosure. Referring to FIG. 2A to FIG. 2C, the testing substrate 200 of the present embodiment has a second build-up structure 130 formed on the first build-up structure 120, so as to be applied to a chip with a high I/O count and more complexity. Specifically, the spacing of the second build-up structure 130 may be smaller than the spacing of the first build-up structure 120, and the second build-up structure 130 may be electrically connected to the first build-up structure 120 to form a fan-out. The manufacturing processes of the testing substrate 200 at least include the following steps. First, as shown in FIG. 2A to FIG. 2B, following the structure of FIG. 1C, the second build-up structure 130 is bonded onto the first build-up structure 120. Specifically, the second build-up structure 130 may be formed on a carrier 20 first. Here, the carrier 20 may be a glass carrier, but the disclosure is not limited thereto.

Further, for example, the second build-up structure 130 may be bonded onto the first build-up structure 120 by a hybrid bonding process. Therefore, the first build-up structure 120 and the second build-up structure 130 has therebetween a first bonding interface S1 of a dielectric-to-dielectric bonding interface and a metal-to-metal bonding interface, but the disclosure is not limited thereto.

Next, as shown in FIG. 2B to FIG. 2C, after the second build-up structure 130 is bonded onto the first build-up structure 120, the carrier 20 can be removed by performing a laser debonding process with a laser tool L. However, the disclosure is not limited thereto, and the carrier 20 may also be removed by other suitable processes. After the above process, the fabrication of the testing substrate 200 of the present embodiment is substantially completed.

In some embodiments, the second build-up structure 130 is formed by alternately stacking a plurality of second patterned conductive layers 132 and a plurality of second dielectric layers 134. The material of the plurality of second patterned conductive layers 132 may include copper, gold, nickel, aluminum, platinum, tin, a combination of the foregoing, an alloy of the foregoing or other suitable conductive materials. The material of the second dielectric layer 134 may include polyimide, benzocyclobutene, polybenzoxazole or other suitable electrical insulating materials.

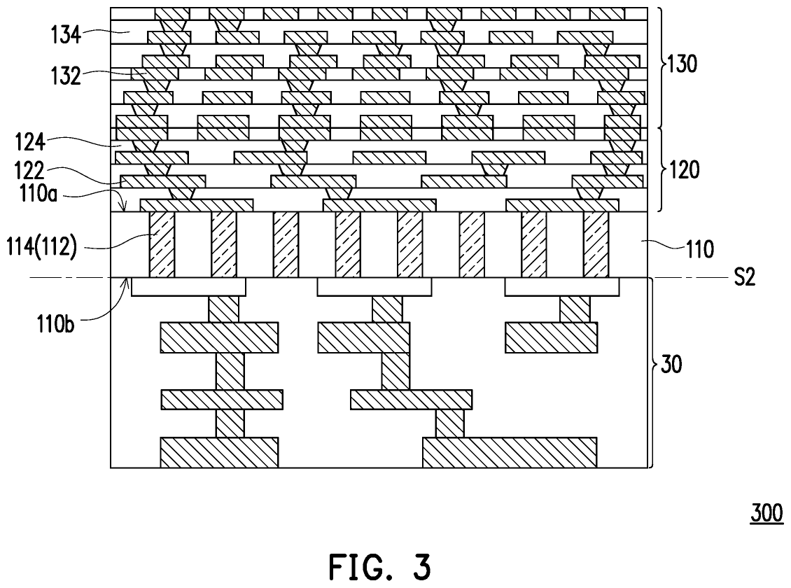

FIG. 3 is a schematic partial cross-sectional view of a testing substrate according to some embodiments of the disclosure. Referring to FIG. 3, compared with the testing substrate 200, the testing substrate 300 of the present embodiment further has a circuit carrier 30 bonded onto the second surface 110b of the substrate 110, so as to be further applied to a chip with a higher I/O count and more complexity. Here, the circuit carrier 30 may include a multi-layer ceramic (MLC) carrier or a multi-layer organic (MLO) carrier.

In some embodiments, when the circuit carrier 30 is a multi-layer ceramic carrier, the circuit carrier 30 may be bonded onto the second surface 110b by a hybrid bonding process, so that the circuit carrier 30 is electrically connected to the substrate 110. Therefore, the substrate 110 and the circuit carrier 30 has therebetween a second bonding interface S of a dielectric-to-dielectric bonding interface and a metal-to-metal bonding interface. Nevertheless, the disclosure is not limited thereto, and in other embodiments, the substrate 110 and the circuit carrier 30 may be bonded in other ways.

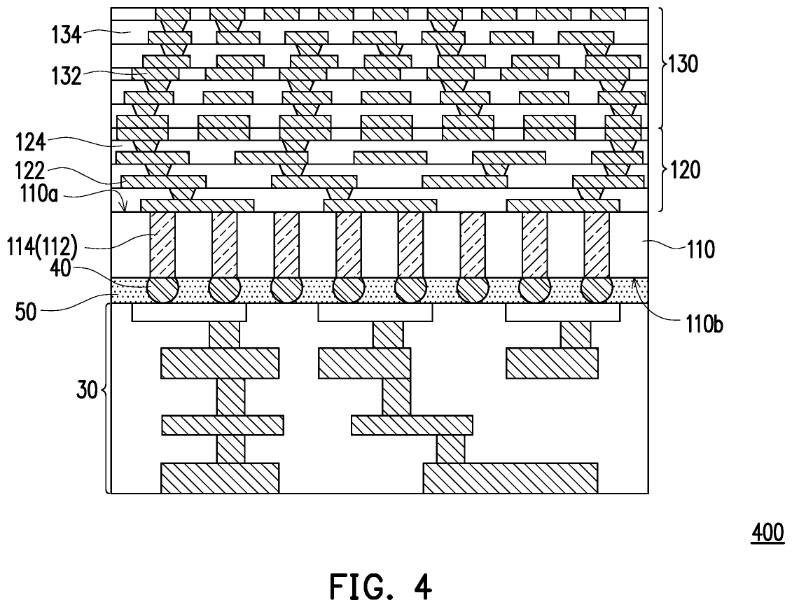

FIG. 4 is a schematic partial cross-sectional view of a testing substrate according to some embodiments of the disclosure. Referring to FIG. 4, compared with the testing substrate 300, the testing substrate 400 of the present embodiment has the circuit carrier 30 bonded onto the second surface 110b through a plurality of conductive terminals 40. In other words, a plurality of conductive terminals 40 may be included between the substrate 110 and the circuit carrier 30. Here, the conductive terminals 40 may be a combination of copper core balls and solder paste, but the disclosure is not limited thereto.

In the present embodiment, the testing substrate 400 further includes an underfill material 50. The underfill material 50 can penetrate between the conductive terminals 40 by capillary action to completely cover each solder joint and be cured by heat, thereby effectively improving the mechanical strength of the solder joint and improving the reliability of the testing substrate 400, but the disclosure is not limited thereto. Here, the underfill material 50 is, for example, epoxy.

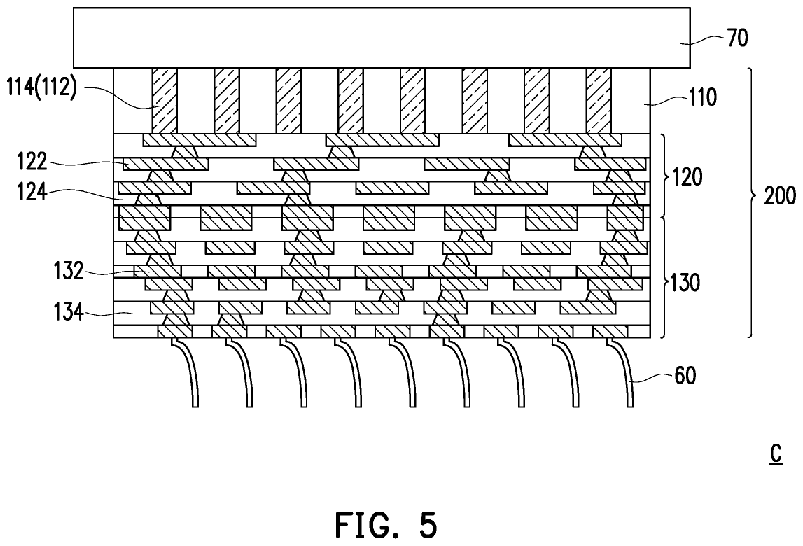

FIG. 5 is a schematic partial cross-sectional view of a probe card according to some embodiments of the disclosure. Referring to FIG. 5, the probe card C of the present embodiment is completed by processing the testing substrate 200 of FIG. 2C. Specifically, the probe card C includes the testing substrate 200, a plurality of probes 60, and a printed circuit board 70. Specifically, the testing substrate 200 is located between the printed circuit board 70 and the plurality of probes 60. Therefore, in the present embodiment, the plurality of probes 60 may be directly arranged on the second build-up structure 130, and the printed circuit board 70 may be electrically connected to the plurality of probes 60 through the testing substrate 200, but the disclosure is not limited thereto. In an embodiment not shown, a probe card can be manufactured using the testing substrate 100 of FIG. 1C in combination with the probes 60 and the printed circuit board 70 described above, so that the probes 60 can be directly arranged on the first build-up structure 120.

In some embodiments, the testing substrate 200 is not reflow bonded to the printed circuit board 70 using solder balls/solder paste, which can prevent poor co-planarity after installation of the probes 60 resulting from deformation during the high-temperature bonding process. Nevertheless, the disclosure is not limited thereto.

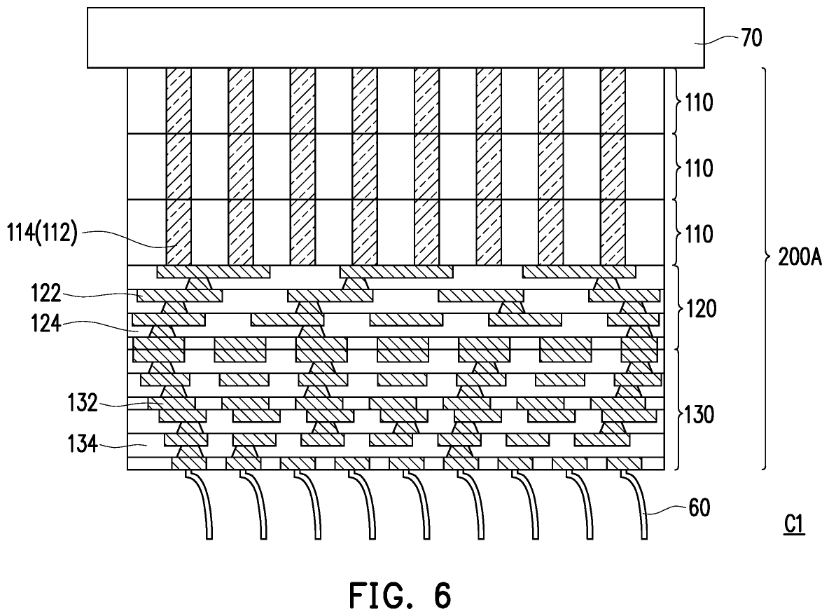

FIG. 6 is a schematic partial cross-sectional view of a probe card according to some embodiments of the disclosure. Referring to FIG. 6, the difference between the probe card Cl of the present embodiment and the probe card C of the embodiment of FIG. 5 is that the testing substrate 200A of the probe card C1 of the present embodiment can be assembled using a plurality of substrates 110 (three are shown), so as to further improve the performance of the probe card C1, but the disclosure is not limited thereto. Further, although the substrates 110 shown in FIG. 6 have the same size, the disclosure is not limited thereto. That is to say, in an embodiment not shown, the substrates 110 may have different sizes. For example, the substrates 110 may be arranged from small to large in the direction from the probes 60 to the printed circuit board 70, or the sizes of the substrates 110 at two ends may be equal to each other and larger than the size of the substrate 110 in the middle. In addition, although FIG. 6 schematically illustrates three substrates 110, the disclosure is not limited thereto. The number of the substrates 110 may be determined according to actual design requirements (for example, 1 to 5).

In conclusion, the testing substrate of the disclosure has a design that combines a plurality of conductive connectors penetrating two surfaces of the substrate and the build-up structure, and during the manufacturing processes, electrical tests can be performed simultaneously on the two surfaces to accurately monitor the production yield. Finally, after the fabrication of the testing substrate is completed, the good products can be taken out simply by cutting the testing substrate, and then the subsequent processes can be performed to complete the probe card required. Accordingly, the manufacturing cost is reduced and the yield and reliability are improved. In addition, when the size of the conductive pattern of the substrate is larger than the size of the conductive pattern of the build-up structure, the spacing between two ends of the testing substrate can be satisfied. Therefore, it is possible to further reduce the manufacturing cost and improve the yield and reliability while satisfying the spacing between two ends of the testing substrate. Furthermore, since the first build-up structure is formed on the substrate by the build-up process, the substrate and the first build-up structure can be bonded without using solder balls or solder paste, which can prevent failure in bridging and bonding the thin film and the substrate after reflow.

Although the disclosure has been described with reference to the above embodiments, they are not intended to limit the disclosure. Those having ordinary knowledge in the art can make changes and modifications without departing from the spirit and scope of the disclosure. Therefore, the scope of the disclosure should be defined by the appended claims.

What is claimed is:

1. A testing substrate, comprising:
a substrate having a first surface and a second surface opposite to each other, wherein the substrate comprises a first conductive pattern, the first conductive pattern comprises a plurality of conductive connectors, and each of the conductive connectors penetrates the substrate from the first surface to the second surface of the substrate; and
a first build-up structure arranged on the first surface, wherein the first build-up structure comprises a second conductive pattern, the first conductive pattern is electrically connected to the second conductive pattern, and a size of the first conductive pattern is larger than or equal to a size of the second conductive pattern.

2. The testing substrate according to claim 1, wherein the first build-up structure comprises a plurality of first patterned conductive layers and a plurality of first dielectric layers that are stacked alternately.

3. The testing substrate according to claim 1, further comprising a second build-up structure arranged on a surface of the first build-up structure opposite to the substrate, wherein a first bonding interface of a dielectric-to-dielectric bonding interface and a metal-to-metal bonding interface is formed between the first build-up structure and the second build-up structure.

4. The testing substrate according to claim 3, wherein the second build-up structure comprises a plurality of second patterned conductive layers and a plurality of second dielectric layers that are stacked alternately.

5. The testing substrate according to claim 1, further comprising a circuit carrier arranged on the second surface, wherein the circuit carrier comprises a multi-layer ceramic carrier or a multi-layer organic carrier.

6. The testing substrate according to claim 5, wherein:
a second bonding interface of a dielectric-to-dielectric bonding interface and a metal-to-metal bonding interface is formed between the substrate and the circuit carrier; or
a plurality of conductive terminals are provided between the substrate and the circuit carrier.

7. A manufacturing method of a testing substrate, comprising:
providing a substrate, wherein the substrate has a first surface and a second surface opposite to each other;
forming a first conductive pattern in the substrate, wherein the first conductive pattern comprises a plurality of conductive connectors, and each of the conductive connectors penetrates the substrate from the first surface to the second surface of the substrate; and
forming a first build-up structure on the first surface by performing a build-up process, wherein the first build-up structure comprises a second conductive pattern, the first conductive pattern is electrically connected to the second conductive pattern, and a size of the first conductive pattern is larger than or equal to a size of the second conductive pattern.

8. The manufacturing method of the testing substrate according to claim 7, further comprising:
bonding a second build-up structure to the first build-up structure by a hybrid bonding process.

9. The manufacturing method of the testing substrate according to claim 7, further comprising:
bonding a circuit carrier to the second surface by a hybrid bonding process; or bonding the circuit carrier to the second surface by a plurality of conductive terminals.

10. A probe card, comprising:
a testing substrate, comprising:
a substrate having a first surface and a second surface opposite to each other, wherein
the substrate has a first conductive pattern, the first conductive pattern comprises a plurality of conductive connectors, and each of the conductive connectors penetrates the substrate from the first surface to the second surface of the substrate; and
a first build-up structure arranged on the first surface, wherein the first build-up structure comprises a second conductive pattern, the first conductive pattern is electrically connected to the second conductive pattern, and a size of the first conductive pattern is larger than or equal to a size of the second conductive pattern; and
a plurality of probes; and
a printed circuit board, wherein the testing substrate is located between the printed circuit board and the plurality of probes.
